(19) United States
(12) Patent Application Publication
(10) Pub. No.: US 2006/0115747 A1
(43) Pub. Date: Jun. 1, 2006

(54) Photo mask structure used during twice-performed photo process and methods of using the same

(76) Inventors: Hyung-Rae Lee, Seoul (KR); Jin-Young Yoon, Seoul (KR); Sang-Gyun Woo, Yongin-si (KR); Man-Hyoung Ryoo, Hwaseong-si (KR); Min-Jeong Oh, Yeonsu-gu (KR)

Correspondence Address: HARNESS, DICKEY & PIERCE, P.L.C., P.O. BOX 8910, RESTON, VA, 20195, US

(21) Appl. No.: 11/281,466

(22) Filed: Nov. 18, 2005

(30) Foreign Application Priority Data
Nov. 27, 2004 (KR) 10-2004-0098352

(51) Int. Cl. G03C 5/00; G03F 1/00

(52) U.S. Cl. 430/5; 430/394; 430/311; 430/312; 430/313

(57) ABSTRACT

A photo mask structure used during a twice-performed photo process and methods of using the same. The photo mask structure may include first mask patterns that correspond to first photoresist patterns during a first photo process performed on a first photoresist layer and second mask patterns that correspond to second photoresist patterns during a second photo process performed on a second photoresist layer. A method of using a photo mask structure may include performing a first photo process on a first photoresist layer using first mask patterns of the photo mask structure to form first photoresist patterns on a semiconductor substrate, and performing a second photo process on a second photoresist layer using second mask patterns of the photo mask structure to form second photoresist patterns on a semiconductor substrate, wherein the second photoresist patterns are interposed between the first photoresist patterns and overlap the first photoresist patterns.

### PRIORITY STATEMENT

This application claims the benefit of Korean Patent Application No. 2004-0098352, filed Nov. 27, 2004, the entire contents of which are incorporated herein by reference.

### BACKGROUND OF THE INVENTION

1. Field of the Invention

Example embodiments of the present invention relate to photo masks and methods of using the same and, more particularly, to photo masks used during a twice-performed photo process and methods of using the same.

2. Description of Related Art

In general, a semiconductor device may include circuit interconnections. The circuit interconnections may be formed using a conductive layer and photoresist patterns sequentially stacked on a semiconductor substrate during performance of an etching process. The photoresist patterns may be formed using a photo process. During the photo process, some process conditions, for example, a bake temperature, may be applied to the photoresist patterns, so as to improve efficiency of the etching process. Further, the photoresist patterns may be arranged over semiconductor substrate to expose a conductive layer, and the etching process may be performed on the conductive layer using photoresist patterns as a mask to form circuit interconnections on a semiconductor substrate.

However, when fabricated with sub-micron design rules, the photoresist patterns may be formed using the photo process not to form the circuit interconnections desirably defined on a semiconductor substrate. This is because the photoresist patterns are highly susceptible to collapse due to their small contact area with the conductive layer under the sub-micron design rules. Further, since the photoresist patterns have small contact areas with the conductive layer, there may be an increased likelihood that the photoresist patterns may collapse on the semiconductor substrate during an etching process. For example, photoresist patterns may collapse on the conductive layer due to a surface tension of a cleaning solution applied during a drying operation of a photo process.

A conventional method may include coating a bottom antireflective coating film on an underlying layer. A resist enhancement lithography assisted by chemical shrink (RELACS) film may be coated on the bottom antireflective coating film. A photoresist film may be formed on the RELACS film and substantially simultaneously, heat may be applied to the photoresist film. Further, the photoresist film may be selectively exposed and/or developed. In this conventional method, photoresist patterns may be formed on the underlying layer.

However, in the above-described conventional method, the photoresist patterns cannot obtain a sufficient mechanical intensity for resisting the semiconductor fabricating processes. The above-described conventional method is merely directed to improving the adhesion between the photoresist patterns and the bottom antireflective coating film using the RELACS film. Accordingly, the photoresist patterns with sub-micron design rules may collapse on the underlying layer during the semiconductor fabricating processes even when the above-described conventional method is used.

### SUMMARY OF THE INVENTION

An example embodiment of the present invention provides a photo mask structure. The photo mask includes first mask patterns that correspond to first photoresist patterns during a first photo process performed on a first photoresist layer, and second mask patterns that correspond to second photoresist patterns during a second photo process performed on a second photoresist layer, the second photoresist patterns are interposed between the first photoresist patterns.

An example embodiment of the present invention provides a method of using a photo mask structure. The method of using a photo mask structure includes performing a first photo process on a first photoresist layer of the photoresist layers using first mask patterns of the photo mask structure to form first photoresist patterns on first predetermined regions of a semiconductor substrate, and performing a second photo process on a second photoresist layer of the photoresist layers using second mask patterns of the photo mask structure to form second photoresist patterns on second predetermined regions of the semiconductor substrate, wherein the second photoresist patterns are interposed between the first photoresist patterns and overlap the first photoresist patterns.

### BRIEF DESCRIPTION OF THE DRAWINGS

Example embodiments of the present invention will be more clearly understood from the description of example embodiments of the present invention, taken in conjunction with the accompanying drawings. The drawings are not necessarily to scale, emphasis instead being placed upon illustrating the principles of the invention.

FIG. 1 shows the layout of a photo mask according to an example embodiment of the present invention.

FIGS. 2 through 7 are cross-sectional views taken along line I-I′ of FIG. 1, which show photoresist patterns according to an example embodiment of the present invention.

FIGS. 8 through 10 are cross-sectional views taken along line I-I′ of FIG. 1, which show photoresist patterns according to another example embodiment of the present invention.

FIGS. 11 through 14 are cross-sectional views of taken along line I-I′ of FIG. 1, which show photoresist patterns according to another example embodiment of the present invention.

FIGS. 15 through 17 are cross-sectional views taken along line I-I′ of FIG. 1, which show photoresist patterns according to another example embodiment of the present invention.

### DETAILED DESCRPTION OF THE INVENTION

Various example embodiments of the present invention will now be described more fully with reference to the accompanying drawings in which some example embodiments of the invention are shown. In the drawings, the thicknesses of layers and regions may be exaggerated for clarity.

Detailed illustrative embodiments of the present invention are disclosed herein. However, specific structural and functional details disclosed herein are merely representative for purposes of describing example embodiments of the present invention. This invention may, however, may be embodied in many alternate forms and should not be construed as limited to only the embodiments set forth herein.

Accordingly, while example embodiments of the invention are capable of various modifications and alternative forms, embodiments thereof are shown by way of example in the drawings and will herein be described in detail. It should be understood, however, that there is no intent to limit example embodiments of the invention to the particular forms disclosed, but on the contrary, example embodiments of the invention are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments of the invention. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the FIGS. For example, two FIGS. shown in succession may in fact be executed substantially concurrently or may sometimes be executed in the reverse order, depending upon the functionality/acts involved.

Photo masks may be used during two performances of a photo process and methods of using the same according to example embodiments of the present invention will now be described more fully hereinafter with reference to the accompanying drawings, in which example embodiments of the invention are shown.

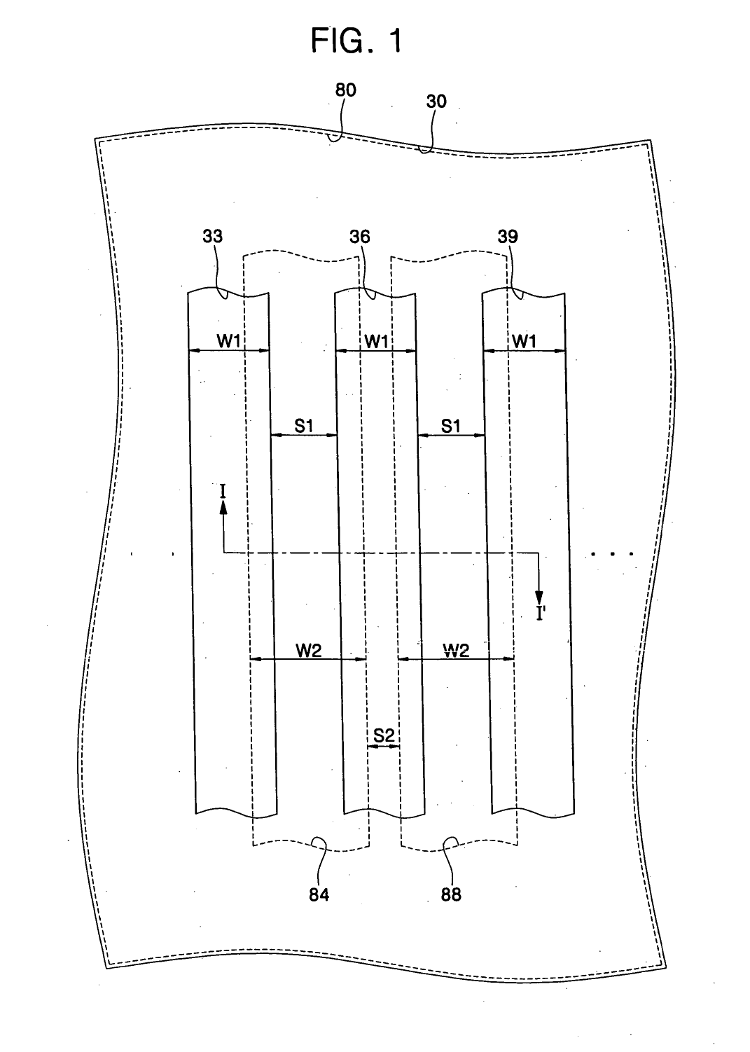

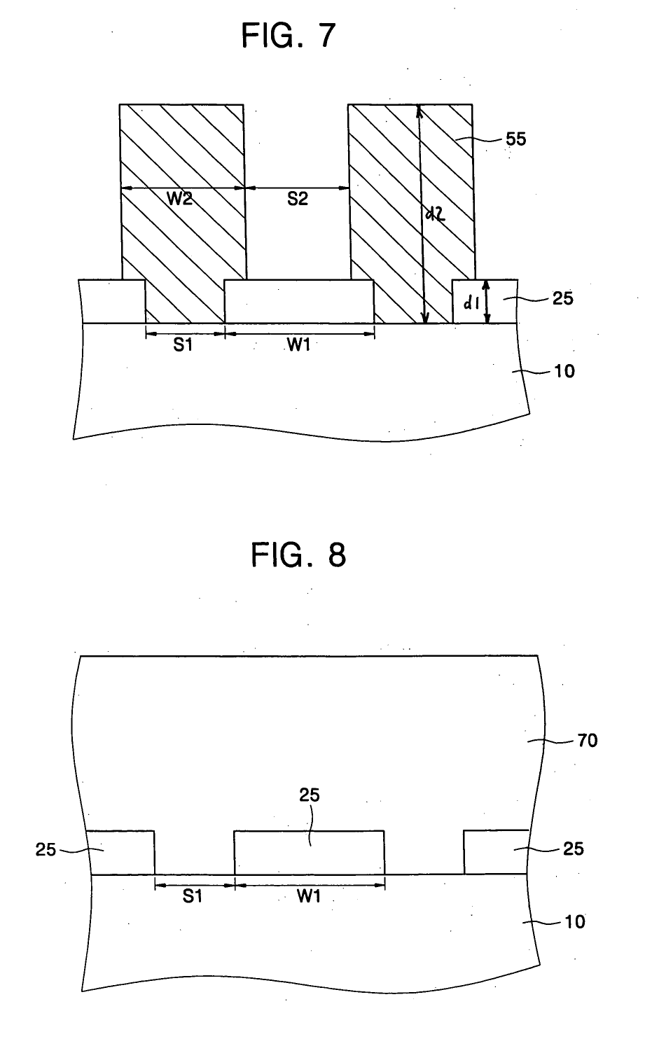

FIG. 1 shows the layout of a photo mask according to an example embodiment of the present invention, and FIGS. 7, 10, 14, and 17 are cross-sectional views taken along line I-I′ of FIG. 1, which show photoresist patterns according to various example embodiments of the present invention.

Referring to example embodiments of the present invention as shown in FIGS. 1, 7, and 14, photoresist patterns (hereinafter, first photoresist patterns) 25 and 105 and/or other photoresist patterns (hereinafter, second photoresist patterns) 55 and 125 may be disposed on a semiconductor substrate 10. Second photoresist patterns 55 and 125 may be interposed between first photoresist patterns 25 and 105 and/or overlap first photoresist patterns 25 and 105, respectively. First photoresist patterns 25 and 105 may have a lower mechanical intensity than second photoresist patterns 55 and 125, may support second photoresist patterns 55 and 125, and may be thinner than second photoresist patterns 55 and 125 (e.g., d1<d2).

Further, first photoresist patterns 25 and 105 and second photoresist patterns 55 and 125 of an example embodiment of the present invention may be obtained by transferring mask patterns (hereinafter, first mask patterns) 33, 36, and 39 of a photo mask (hereinafter, a first photo mask) 30 onto different photoresist layers (not shown) during two photo processes. First mask patterns 33, 36, and 39 may be disposed apart from each other on a first photo mask 30, and first mask patterns 33, 36, and 39 may correspond to first photoresist patterns 25 and 105 during a first photo process that may be performed on one of the photoresist layers (hereinafter, a first photoresist layer). Also, first mask patterns 33, 36, and 39 may correspond to second photoresist patterns 55 and 125 during a second photo process that may be performed on other photoresist layers (hereinafter, a second photoresist layer), such that they may be disposed between the first photoresist patterns 25 and 105.

According to an example embodiment of the present invention, first photoresist layers may be a positive-tone resist, and second photoresist layer may be a negative-tone resist. For example, as shown in FIG. 7, first photoresist patterns 25 and the second photoresist patterns 55 may correspond to positive-tone resist patterns and negative-tone resist patterns, respectively. Pitch (W2+S2) of each of the second photoresist patterns 55 may be different from pitch (W1+S1) of each of the first photoresist patterns 25. According to an alternative example embodiment of the present invention, the pitch (W2+S2) of each of the second photoresist patterns 55 may be equal to the pitch (W1+S1) of each of the first photoresist patterns 25. For example, when a second photoresist layer is a negative-tone resist, second photoresist patterns 55 may have the same pitch (W2+S2) as other mask patterns (hereinafter, second mask patterns) 84 and 88 of another photo mask (hereinafter, a second photo mask) 80 shown in FIG. 1.

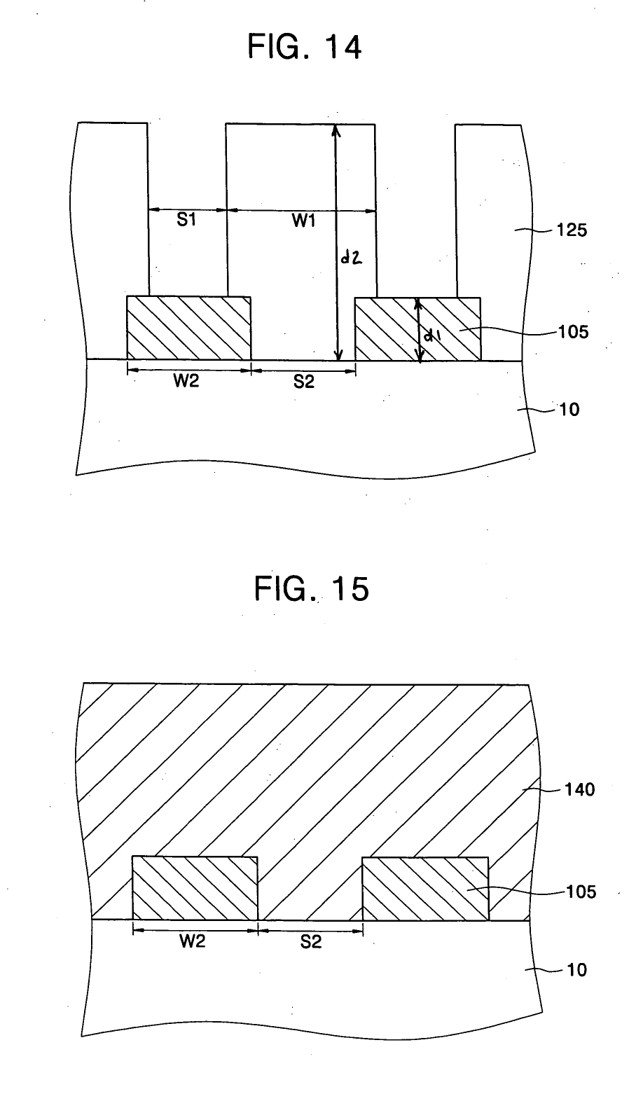

According to an example embodiment of the present invention, first photoresist layers may be a negative-tone resist and a second photoresist layer may be a positive-tone resist. For example, as shown in FIG. 14, first photoresist patterns 105 and second photoresist patterns 125 may correspond to negative-tone resist patterns and positive-tone resist patterns, respectively. Further, a pitch (W1+S1) of each of the second photoresist patterns 125 may be different from pitch (W2+S2) of each of the first photoresist patterns 105. Alternatively, pitch (W1+S1) of each of the second photoresist patterns 125 may be equal to pitch (W2+S2) of each of the first photoresist patterns 105. For example, when a first photoresist layer is a negative-tone resist, first photoresist patterns 105 may have the same pitch (W2+S2) as second mask patterns 84 and 88 of second photo mask 80. First photo mask 30 may be irradiated with light produced by a photo light source selected from a group including, but not limited to, deep ultraviolet (DUV), KrF, and ArF. First photo mask 30 may be a binary mask and/or a phase shift mask, for example.

Referring to example embodiments of the present invention as shown in FIGS. 1, 10, and 17, first photoresist patterns 25 and 105 and/or second photoresist patterns 75 and 145 may be disposed on a semiconductor substrate 10. For example, second photoresist patterns 75 and 145 may be interposed between first photoresist patterns 25 and 105 and/or overlap first photoresist patterns 25 and 105. In an example embodiment of the present invention, first photoresist patterns 25 and 105 may have a lower mechanical intensity than second photoresist patterns 75 and 145, may support second photoresist patterns 75 and 145, and may be thinner than second photoresist patterns 75 and 145 (e.g., d1<d2).

Further, first photoresist patterns 25 and 105 and second photoresist patterns 75 and 145 may be obtained by transferring first mask patterns 33, 36, and 39 of a first photo mask 30 and second mask patterns 84 and 88 of a second photo mask 80 onto different photoresist layers (not shown) during two photo processes. In an example embodiment of the present invention, first mask patterns 33, 36, and 39 may be disposed apart from each other on a first photo mask 30, and second mask patterns 84 and 88 may be disposed apart from each other on a second photo mask 80. Accordingly, first mask patterns 33, 36, and 39 may correspond to first photoresist patterns 25 and 105 during a first photo process that may be performed on a first photoresist layer of the photoresist layers. Also, second mask patterns 84 and 88 may correspond to second photoresist patterns 75 and 145 during a second photo process that may be performed on a second photoresist layer of the photoresist layers, for example, second photoresist patterns 75 and 145 may be disposed between first photoresist patterns 25 and 105.

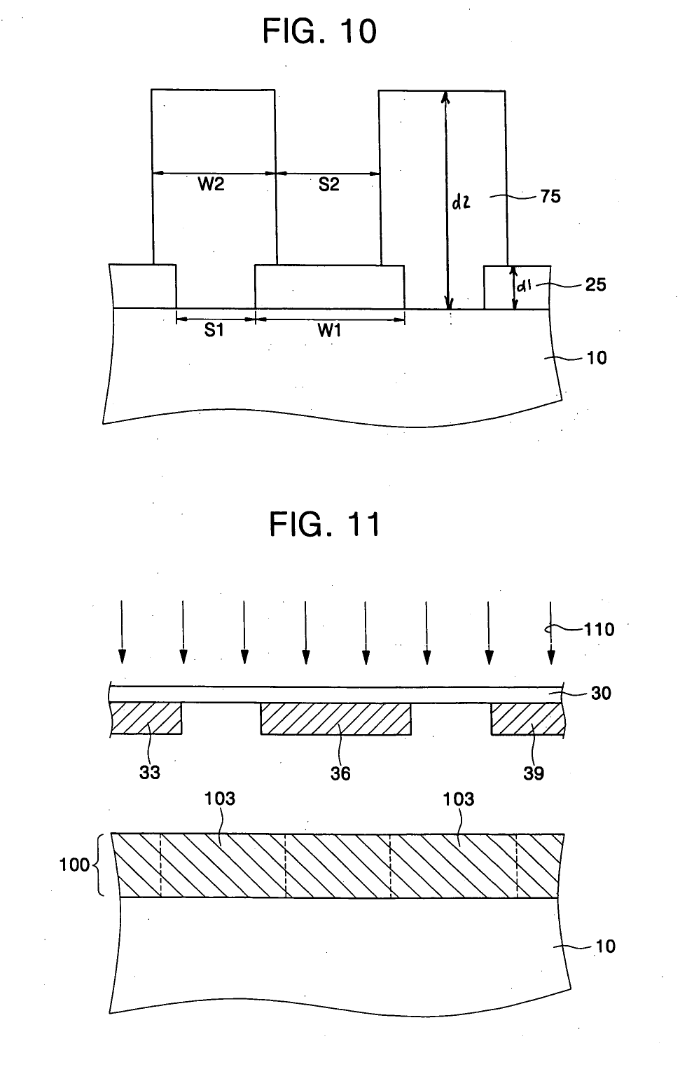

In an example embodiment of the present invention, photoresist layers may be positive-tone resists. For example, as shown in FIG. 10, first photoresist patterns 25 and second photoresist patterns 75 may correspond to positive-tone resist patterns. Pitch (W2+S2) of each of the second photoresist patterns 75 may be different from pitch (W1+S1) of each of the first photoresist patterns 25. Alternatively, pitch (W2+S2) of each of the second photoresist patterns 75 may be equal to pitch (W1+S1) of each of the first photoresist patterns 25.

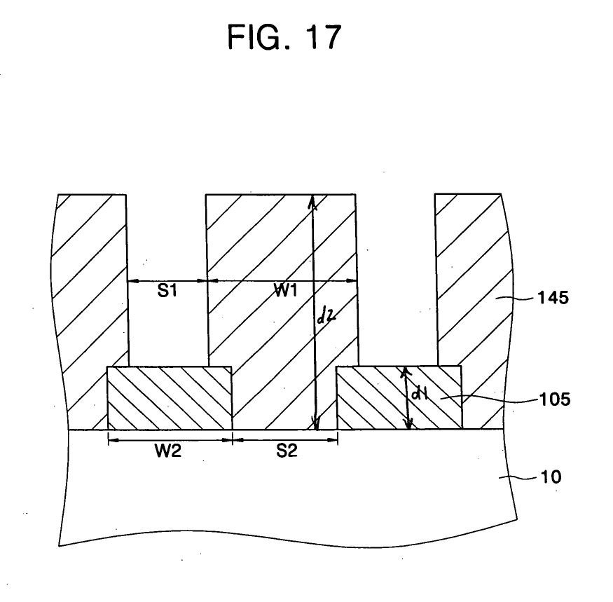

Inversely, according to an example embodiment of the present invention, photoresist layers may be negative-tone resists. For example, as shown in FIG. 17, first photoresist patterns 105 and the second photoresist patterns 145 may correspond to negative-tone resist patterns. Pitch (W1+S1) of each of the second photoresist patterns 145 may be different from pitch (W2+S2) of each of the first photoresist patterns 105. Alternatively, the pitch (W1+S1) of each of the second photoresist patterns 145 may be equal to the pitch (W2+S2) of each of the first photoresist patterns 105. For example, first photoresist patterns 25 and 105 with pitches (W1+S1, W2+S2) may be disposed on predetermined regions (hereinafter, first predetermined regions) of semiconductor substrate 10 through the first mask patterns 33, 36, and 39 of first photo mask 30. Further, second photoresist patterns 75 and 145 with pitches (W2+S2, W1+S1) may be disposed on other predetermined regions (hereinafter, second predetermined regions) of semiconductor substrate 10 through second mask patterns 84 and 88 of second photo mask 80.

According to an example embodiment of the present invention, first photo mask 30 and second photo mask 80 may be irradiated with light produced by a photo light source selected from a group including, but not limited to, DUV, KrF, and ArF. Each of first photo mask 30 and second photo mask 80 may be a binary mask and/or a phase shift mask, for example.

Hereinafter, methods of using photo masks used during two or more photo processes according to example embodiments of the present invention will be described.

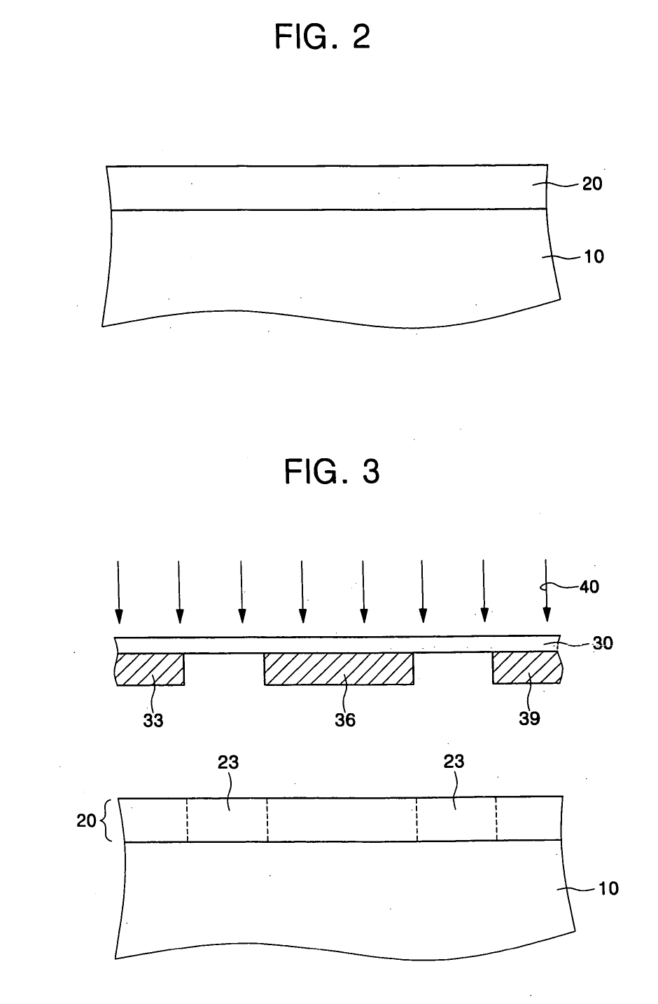

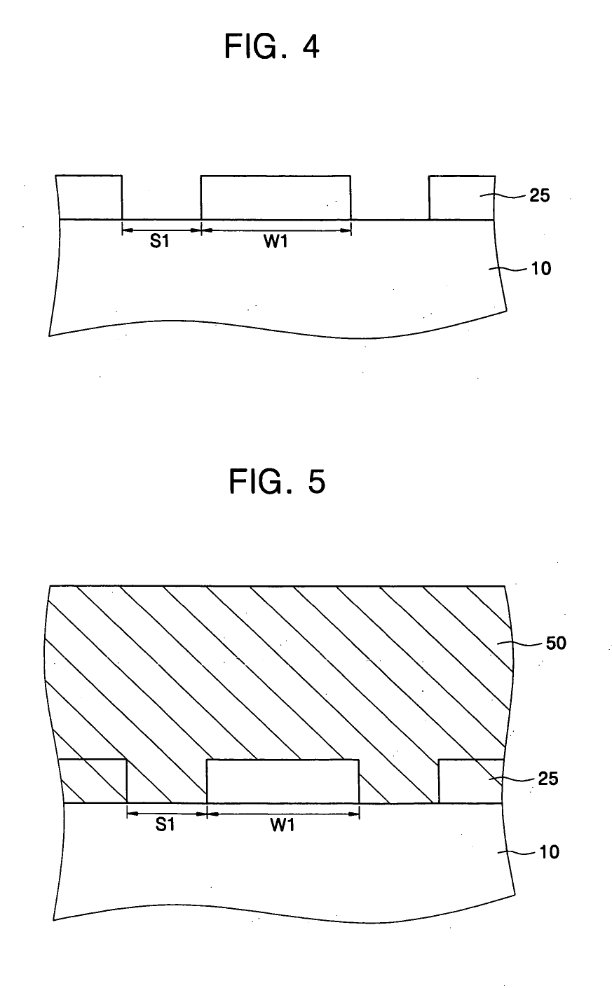

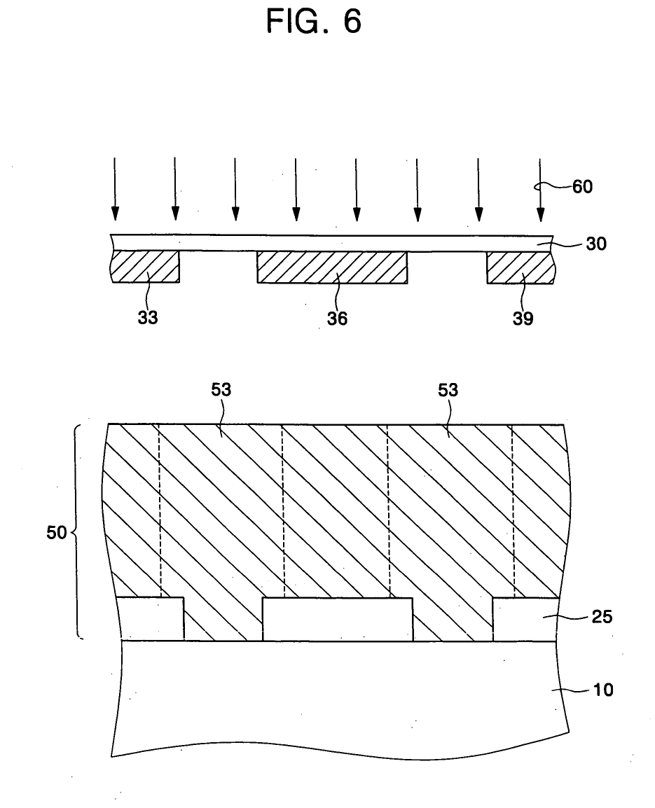

FIGS. 2 through 7 are cross-sectional views taken along line I-I′ of FIG. 1, which show photoresist patterns according to an example embodiment of the present invention.

Referring to an example embodiment of the present invention as shown in FIGS. 1 through 4, a first photoresist layer 20 may be formed on a semiconductor substrate 10. The first photoresist layer 20 may be formed using a positive-tone resist. According to an example embodiment of the present invention, before the first photoresist layer 20 is formed, an anti-reflective layer (not shown) may be formed on the semiconductor substrate 10. First photoresist layer 20 may be disposed under a first photo mask 30. First photo mask 30 may be a binary mask and/or a phase shift mask, for example. First photo mask 30 may include first mask patterns 33, 36, and 39, which may be spaced apart from each other. Thereafter, according to an example embodiment of the present invention, a first photo process may be performed on a first photoresist layer 20. The first photo process may include one or more of an exposure operation, a developing operation, and a drying operation.

In an exposure operation of an example embodiment of the present invention, first mask patterns 33, 36, and 39 may be transferred on first photoresist layer 20 using first photo mask 30. In an example embodiment of the present invention, an exposure operation may be performed using a photo light source 40 selected from a group including, but not limited to, DUV, KrF, and ArF. During an exposure operation, bond strength between polymers in predetermined portions 23 of first photoresist layer 20, which may react with the photo light source 40, may be weakened using a photo acid generator (PAG), which may be included in a first photoresist layer 20 and may react with photo light source 40.

In a developing operation of an example embodiment of the present invention, first photoresist layer 20, which may have undergone an exposure operation, may be developed using a developing solution. A developing solution may remove predetermined portions 23 of first photoresist layer 20 in which the bond strength between the polymers is weakened. Accordingly, first photoresist patterns 25 may be formed on first predetermined regions of semiconductor substrate 10.

In a drying operation of an example embodiment of the present invention, first photoresist patterns 25 may be rinsed using deionized water. As a result, particles present around first photoresist patterns 25 and/or on semiconductor substrate 10 may be removed. Thereafter, according to an example embodiment of the present invention, first photoresist patterns 25 may be dried using a spin drying process. In an example embodiment of the present invention, first photoresist patterns 25 may be formed to a predetermined pitch (W1+S1), for example, corresponding to first mask patterns 33, 36, and 39 of first photo mask 30.

Referring to an example embodiment of the present invention as shown in FIGS. 1, 5, 6, and 7, a second photoresist layer 50 may be formed on semiconductor substrate 10 to cover at least a portion of first photoresist patterns 25. Second photoresist layer 50 may be formed using a negative-tone resist, for example. According to an example embodiment of the present invention, before second photoresist layer 50 is formed, contact enhancement treatment may be performed on the semiconductor substrate 10 having the first photoresist patterns 25. A contact enhancement treatment may be performed using a hexamethyldisilazane (HDMS). According to an example embodiment of the present invention, second photoresist layer 50 may be disposed under first photo mask 30 as shown in an example embodiment of the present invention in FIG. 1. Accordingly, first photo mask 30 may include first mask patterns 33, 36, and 39, which may be spaced apart from each other. Thereafter, a second photo process may be performed on a second photoresist layer 50. A second photo process may include one or more of an exposure operation, a developing operation, and a drying operation.

In an exposure operation of an example embodiment of the present invention, first mask patterns 33, 36, and 39 may be transferred on a second photoresist layer 50 using first photo mask 30. An exposure operation may be performed using a photo light source 60 selected from a group including, but not limited to, DUV, KrF, and ArF. During an exposure operation according to an example embodiment of the present invention, bond strength between polymers in predetermined portions 53 of second photoresist layer 50, which may react with photo light source 60, may be reinforced using properties of the negative-tone resist.

In a developing operation of an example embodiment of the present invention, a second photoresist layer 50, which may have undergone an exposure operation, may be developed using a developing solution. A developing solution may enable removal of portions of a second photoresist layer 50 other than predetermined portions 53 in which the bond strength between the polymers may be reinforced. Accordingly, second photoresist patterns 55 may be formed on second predetermined regions of the semiconductor substrate 10.

In a drying operation of an example embodiment of the present invention, second photoresist patterns 55 may be rinsed using deionized water and/or surfactant. Accordingly, particles present around second photoresist patterns 55 and/or on semiconductor substrate 10 may be removed. The surfactant may serve to prevent second photoresist patterns 55 from collapsing on semiconductor substrate 10 due to drops of water. Second photoresist patterns 55 may be dried using a spin drying process, for example. In an example embodiment of the present invention, second photoresist patterns 55 may be formed having a pitch (W2+S2) using first photo mask 30. For example, when second photoresist layer 50 is a negative-tone resist, second photoresist patterns 55 may be formed having the same pitch (W2+S2) as second mask patterns 84 and 88 of a second photo mask 80 through the first mask patterns 33, 36, and 39.

According to an example embodiment of the present invention, second photoresist patterns 55 may substantially fill spaces between first photoresist patterns 25 and/or overlap first photoresist patterns 25. First photoresist patterns 25 may be formed thinner than second photoresist patterns 55 (e.g., d1<d2), and may have a lower mechanical intensity than second photoresist patterns 55. According to an example embodiment of the present invention, different mechanical intensities between first photoresist patterns 25 and second photoresist patterns 55 during first and second photo processes may be obtained. First photoresist patterns 25 may be formed to support second photoresist patterns 55. Pitch (W2+S2) of each of the second photoresist patterns 55 may be different from pitch (W1+S1) of each of the first photoresist patterns 25. Alternatively, pitch (W2+S2) of each of the second photoresist patterns 55 may be equal to pitch (W1+S1) of each of the first photoresist patterns 25. According to an example embodiment of the present invention, because the surfactant may prevent second photoresist patterns 55 from collapsing during a drying operation, the thickness of a second photoresist layer 50 may be increased. Accordingly, a method according to an example embodiment of the present invention may improve efficiency of an etching process using first photoresist patterns 25 and the second photoresist patterns 55.

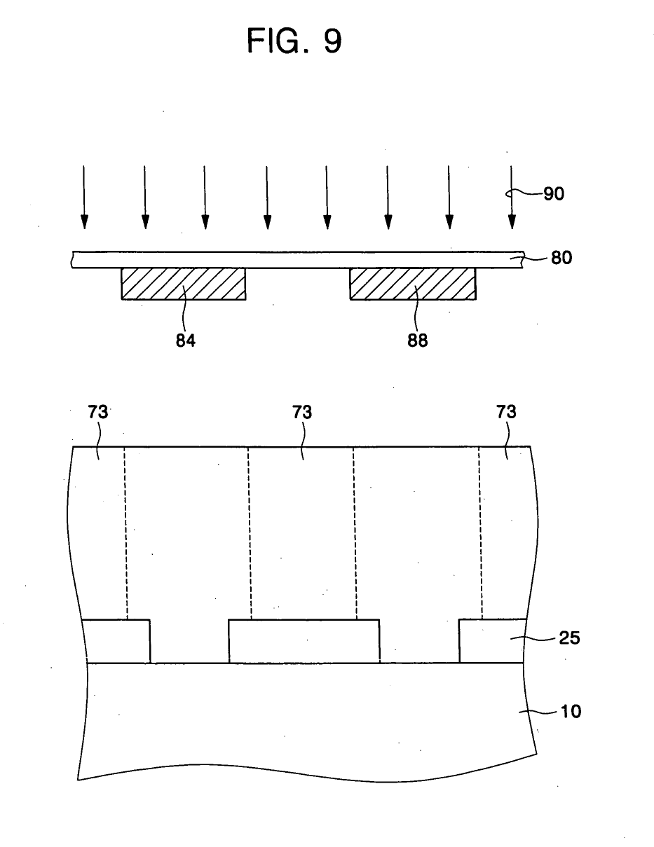

FIGS. 8 through 10 are cross-sectional views taken along line I-I′ of FIG. 1 and show photoresist patterns according to an example embodiment of the present invention. FIG. 8 shows a semiconductor substrate 10 on which first photoresist patterns 25 may be formed according to an example embodiment of the present invention.

Referring to an example embodiment of the present invention as shown in FIGS. 1, 8, 9, and 10, a second photoresist layer 70 may be formed on semiconductor substrate 10 to cover first photoresist patterns 25. Second photoresist layer 70 may be formed using a positive-tone resist. According to an example embodiment of the present invention, before second photoresist layer 70 is formed, contact enhancement treatment may be performed on a semiconductor substrate 10 having first photoresist patterns 25. A contact enhancement treatment may be performed using an HDMS. Second photoresist layer 70 may be disposed under a second photo mask 80. Second photo mask 80 may include second mask patterns 84 and 88, which may be spaced apart from each other. Second photo mask 80 may be a binary mask and/or a phase shift mask, for example. Thereafter, according to an example embodiment of the present invention, a second photo process may be performed on a second photoresist layer 70. A second photo process may include one or more of an exposure operation, a developing operation, and a drying operation according to example embodiments of the present invention.

In an exposure operation of an example embodiment of the present invention, second mask patterns 84 and 88 may be transferred on a second photoresist layer 70 using second photo mask 80. According to an example embodiment of the present invention, an exposure operation may be performed using a photo light source 90 selected from a group including, but not limited to, DUV, KrF, and ArF. During an exposure operation of an example embodiment of the present invention, bond strength between polymers in predetermined portions 73 of second photoresist layer 70, which may react with photo light source 90, may be weakened using a PAG (photo acid generator) which may be included in the second photoresist layer 70 that may react with the photo light source 90.

In a developing operation of an example embodiment of the present invention, second photoresist layer 70, which may have undergone an exposure operation, may be developed using a developing solution. A developing solution may remove predetermined portions 73 of a second photoresist layer 70 in which the bond strength between the polymers may be weakened. Accordingly, second photoresist patterns 75 may be formed on second predetermined regions of the semiconductor substrate 10.

In a drying operation of an example embodiment of the present invention, second photoresist patterns 75 may be rinsed using deionized water and/or surfactant. Particles present around second photoresist patterns 75 and/or on semiconductor substrate 10 may be removed. The surfactant may serve to prevent second photoresist patterns 75 from collapsing on a semiconductor substrate 10 due to drops of water. Thereafter, second photoresist patterns 75 may be dried using a spin drying process. According to an example embodiment of the present invention, second photoresist patterns 75 may be formed with the same pitch (W2+S2) as second photoresist patterns 55 shown in FIG. 7 using second photo mask 80. For example, by making use of the first mask patterns 33, 36, and 39 of first photo mask 30 and second mask patterns 84 and 88 of the second photo mask 80, the first photoresist patterns 25 and the second photoresist patterns 75, which have different pitches (W1+S1, W2+S2) from each other, may be disposed on first predetermined regions and second predetermined regions of semiconductor substrate 10, respectively.

According to an example embodiment of the present invention, second photoresist patterns 75 may substantially fill spaces between the first photoresist patterns 25 and/or overlap first photoresist patterns 25, may be thinner than the second photoresist patterns 75 (e.g., d1<d2), and may be formed having a lower mechanical intensity than the second photoresist patterns 75. Further, according to an example embodiment of the present invention, a different mechanical intensity between first photoresist patterns 25 and second photoresist patterns 75 during the first and second photo processes may be obtained. First photoresist patterns 25 may be formed to support the second photoresist patterns 75. Also, the pitch (W2+S2) of each of the second photoresist patterns 75 may be different from the pitch (W1+S1) of each of the first photoresist patterns 25. Alternatively, the pitch (W2+S2) of each of the second photoresist patterns 75 may be equal to the pitch (W1+S1) of each of the first photoresist patterns 25. Further, since surfactant may prevent second photoresist patterns 75 from collapsing during a drying operation, the thickness of second photoresist layer 70 may be increased according to an example embodiment of the present invention. Accordingly, a method according to an example embodiment of the present invention may improve the efficiency of an etching process using first photoresist patterns 25 and second photoresist patterns 75.

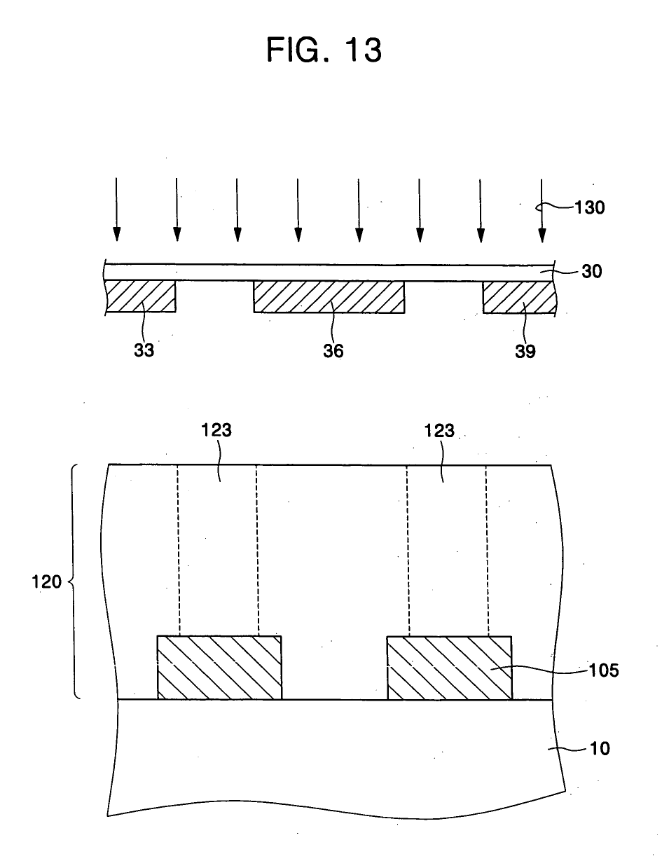

An example embodiment of the present invention as shown in FIGS. 11 through 14 are cross-sectional views taken along line I-I′ of FIG. 1, which show photoresist patterns according to an example embodiment of the present invention.

Referring to an example embodiment of the present invention as shown in FIGS. 1, 11, and 12, a first photoresist layer 100 may be formed on a semiconductor substrate 10. A first photoresist layer 100 may be formed using a negative-tone resist. According to an example embodiment of the present invention, before a first photoresist layer 100 is formed, an anti-reflective layer (not shown) may be formed on semiconductor substrate 10. First photoresist layer 100 may be disposed under a first photo mask 30. First photo mask 30 may include first mask patterns 33, 36, and 39, which may be spaced apart from each other. Thereafter, a first photo process may be performed on first photoresist layer 100. The first photo process of an example embodiment of the present invention may include one or more of an exposure operation, a developing operation, and a drying operation.

In an exposure operation of an example embodiment of the present invention, first mask patterns 33, 36, and 39 may be transferred on first photoresist layer 100 using a first photo mask 30. An exposure operation may be performed using a photo light source 110 selected from a group including, but not limited to, DUV, KrF, and ArF. During an exposure operation of an example embodiment of the present invention, bond strength between polymers in predetermined portions 103 of the first photoresist layer 100, which may react with the photo light source 110, may be reinforced using the properties of a negative-tone resist.

In a developing operation of an example embodiment of the present invention, first photoresist layer 100, which may have undergone an exposure operation, may be developed using a developing solution. A developing solution may enable the removal of portions of first photoresist layer 100 other than the predetermined portions 103 in which the bond strength between the polymers is reinforced. Accordingly, first photoresist patterns 105 may be formed on first predetermined regions of a semiconductor substrate 10.

In a drying operation of an example embodiment of the present invention, first photoresist patterns 105 may be rinsed using deionized water. As a result, particles present around first photoresist patterns 105 and/or on semiconductor substrate 10 may be removed. Thereafter, first photoresist patterns 105 may be dried using a spin drying process. In an example embodiment of the present invention, first photoresist patterns 105 may be formed with a pitch (W2+S2), for example, corresponding to first mask patterns 33, 36, and 39 of first photo mask 30.

A second photoresist layer 120 of an example embodiment of the present invention may be formed on semiconductor substrate 10 to cover at least part of first photoresist patterns 105. A second photoresist layer 120 may be formed using a positive-tone resist. According to an example embodiment of the present invention, before a second photoresist layer 120 is formed, contact enhancement treatment may be performed on a semiconductor substrate 10 having a first photoresist patterns 105. The contact enhancement treatment may be performed using an HDMS, for example.

Referring to an example embodiment of the present invention as shown in FIGS. 1, 13, and 14, second photoresist layer 120 may be disposed under first photo mask 30. A first photo mask 30 may include first mask patterns 33, 36, and 39, which may be spaced apart from each other. Thereafter, a second photo process may be performed on a second photoresist layer 120. A second photo process may include one or more of an exposure operation, a developing operation, and a drying operation.

In an exposure operation of an example embodiment of the present invention, first mask patterns 33, 36, and 39 may be transferred on a second photoresist layer 120 using first photo mask 30. In an example embodiment of the present invention, an exposure operation may be performed using a photo light source 130 selected from a group including, but not limited to, DUV, KrF, and ArF. During an exposure operation of an example embodiment of the present invention, bond strength between polymers in predetermined portions 123 of second photoresist layer 120, which may react with the photo light source 130, may be weakened using a PAG (photo acid generator) which may be included in the second photoresist layer 120 that may react with the photo light source 130.

In a developing operation of an example embodiment of the present invention, the second photoresist layer 120, which may have undergone an exposure operation, may be developed using a developing solution. A developing solution may enable the removal of predetermined portions 123 of a second photoresist layer 120 in which the bond strength between the polymers may be weakened. Accordingly, second photoresist patterns 125 may be formed on second predetermined regions of the semiconductor substrate 10.

In a drying operation of an example embodiment of the present invention, second photoresist patterns 125 may be rinsed using deionized water and/or surfactant. As a result, particles present around second photoresist patterns 125 and/or on semiconductor substrate 10 may be removed. Surfactant may serve to prevent second photoresist patterns 125 from collapsing on semiconductor substrate 10 due to drops of water. Thereafter, second photoresist patterns 125 may be dried using a spin drying process. In an example embodiment of the present invention, second photoresist patterns 125 may be formed having a pitch (W1+S1) using a first photo mask 30. For example, when a first photoresist layer 100 is a negative-tone resist, first photoresist patterns 105 may be formed with the same pitch (W2+S2) as the second mask patterns 84 and 88 of second photo mask 80 shown in FIG. 1 through the first mask patterns 33, 36, and 39.

Second photoresist patterns 125 of an example embodiment of the present invention may substantially fill spaces between first photoresist patterns 105 and/or overlap first photoresist patterns 105. First photoresist patterns 105 may be formed thinner than the second photoresist patterns 125 (e.g., d1<d2), and may be formed having a lower mechanical intensity than second photoresist patterns 125. According to an example embodiment of the present invention, a different mechanical intensity between first photoresist patterns 105 and second photoresist patterns 125 during the first and second photo processes may be obtained. First photoresist patterns 105 may be formed to support the second photoresist patterns 125. Also, pitch (W1+S1) of each of the second photoresist patterns 125 may be different from pitch (W2+S2) of each of the first photoresist patterns 105. Alternatively, pitch (W1+S1) of each of the second photoresist patterns 125 may be equal to pitch (W2+S2) of each of the first photoresist patterns 105. Since the surfactant may prevent the second photoresist patterns 125 from collapsing during a drying operation, the thickness of a second photoresist layer 120 may be increased according to an example embodiment of the present invention. Accordingly, a method according to an example embodiment of the present invention may improve the efficiency of an etching process using the first photoresist patterns 105 and the second photoresist patterns 125.

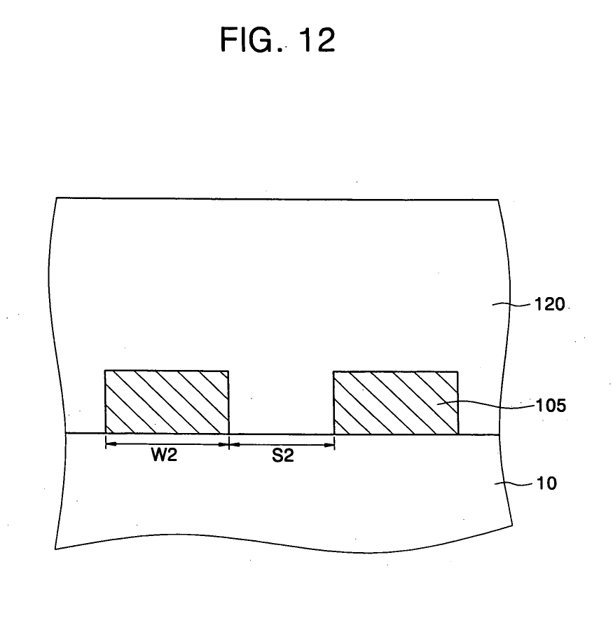

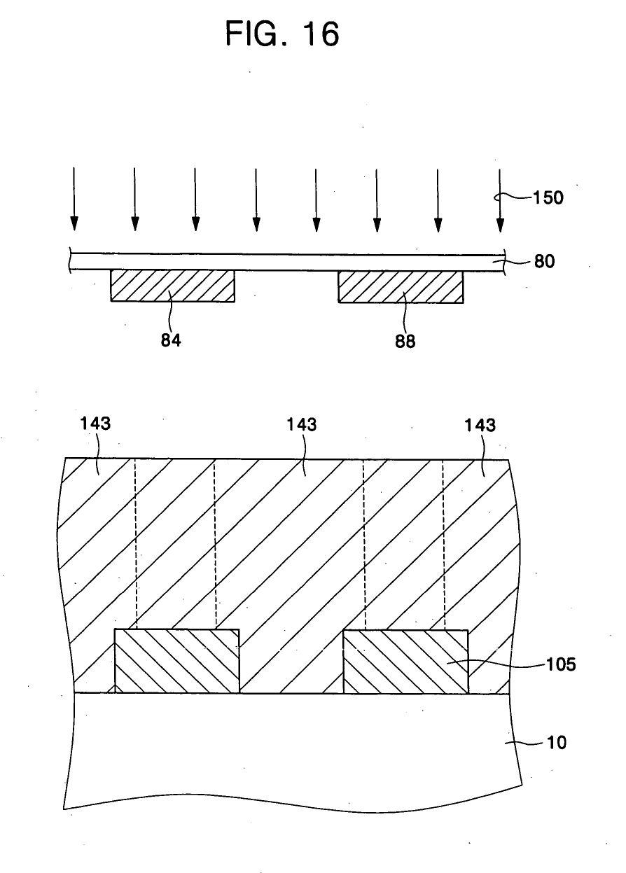

FIGS. 15 through 17 are cross-sectional views taken along line I-I′ of FIG. 1, which show photoresist patterns according to an example embodiment of the present invention. FIG. 15 shows a semiconductor substrate 10 on which first photoresist patterns 105 obtained according to an example embodiment of the present invention as shown in FIGS. 11 and 12 may be formed.

Referring to an example embodiment of the present invention as shown in FIGS. 1, 15, 16, and 17, a second photoresist layer 140 may be formed on semiconductor substrate 10 to cover at least a portion of the first photoresist patterns 105. Second photoresist layer 140 may be formed using a negative-tone resist. According to an example embodiment of the present invention, before the second photoresist layer 140 is formed, contact enhancement treatment may be performed on semiconductor substrate 10 having the first photoresist patterns 105. A contact enhancement treatment may be performed using an HDMS. Second photoresist layer 140 may be disposed under second photo mask 80. Accordingly, second photo mask 80 may include second mask patterns 84 and 88, which may be spaced apart from each other. Thereafter, according to an example embodiment of the present invention, a second photo process may be performed on second photoresist layer 140. A second photo process may include one or more of an exposure operation, a developing operation, and a drying operation.

In an exposure operation of an example embodiment of the present invention, second mask patterns 84 and 88 may be transferred on a second photoresist layer 140 using a second photo mask 80. An exposure operation may be performed using a photo light source 150 selected from a group including, but not limited to, DUV, KrF, and ArF. During an exposure operation according to an example embodiment of the present invention, bond strength between polymers in predetermined portions 143 of a second photoresist layer 140, which may react with photo light source 150, may be reinforced using the properties of the negative-tone resist.

In a developing operation of an example embodiment of the present invention, second photoresist layer 140, which may have undergone an exposure operation, may be developed using a developing solution. A developing solution may enable the removal of portions of second photoresist layer 140 other than predetermined portions 143 in which the bond strength between the polymers may be reinforced. Accordingly, second photoresist patterns 145 may be formed on second predetermined regions of semiconductor substrate 10.

In a drying operation of an example embodiment of the present invention, second photoresist patterns 145 may be rinsed using deionized water and/or surfactant. Particles present around second photoresist patterns 145 and/or on semiconductor substrate 10 may be removed. The surfactant may serve to prevent second photoresist patterns 145 from collapsing on semiconductor substrate 10 due to drops of water. Thereafter, second photoresist patterns 145 may be dried using a spin drying process. In an example embodiment of the present invention, second photoresist patterns 145 may be formed with a pitch (W1+S1) using second photo mask 80. For example, by using first mask patterns 33, 36, and 39 of first photo mask 30 and second mask patterns 84 and 88 of second photo mask 80, the first photoresist patterns 105 and the second photoresist patterns 145, which may have different pitches (W2+S2, W1+S1) from each other, may be disposed on the first predetermined regions and the second predetermined regions of the semiconductor substrate 10, respectively.

According to an example embodiment of the present invention, second photoresist patterns 145 may at least partially fill spaces between first photoresist patterns 105 and/or overlap first photoresist patterns 105. Further, first photoresist patterns 105 may be formed thinner than the second photoresist patterns 145 (e.g., d1<d2), and may have a lower mechanical intensity than second photoresist patterns 145. According to an example embodiment of the present invention, a different mechanical intensity between first photoresist patterns 105 and second photoresist patterns 145 during the first and second photo processes may be obtained. First photoresist patterns 105 may be formed to support second photoresist patterns 145. Pitch (W1+S1) of each of the second photoresist patterns 145 may be different from pitch (W2+S2) of each of first photoresist patterns 105. Alternatively, pitch (W1+S1) of each of second photoresist patterns 145 may be equal to pitch (W2+S2) of each of first photoresist patterns 105. Since the surfactant may prevent second photoresist patterns 145 from collapsing during a drying operation, the thickness of second photoresist layer 140 may be increased according to an example embodiment of the present invention. Accordingly, a method according to an example embodiment of the present invention may improve the efficiency of an etching process using first photoresist patterns 105 and second photoresist patterns 145.

According to of an example embodiment of the present invention as described above, first photoresist patterns and second photoresist patterns may be formed on a semiconductor substrate using different photoresist layers. Further, second photoresist patterns may at least partially fill spaces between first photoresist patterns and/or overlap first photoresist patterns. Also, second photoresist patterns may be formed to have a larger thickness and a higher mechanical intensity than first photoresist patterns. Accordingly, example embodiments of the present invention may improve the efficiency of an etching process using first photoresist patterns and/or second photoresist patterns.

Example embodiments of the present invention have been disclosed herein and, although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A photo mask structure comprising:
first mask patterns that correspond to first photoresist patterns during a first photo process performed on a first photoresist layer; and
second mask patterns that correspond to second photoresist patterns during a second photo process performed on a second photoresist layer, wherein the second photoresist patterns are interposed between the first photoresist patterns.

2. The photo mask structure according to claim 1, wherein the first photoresist patterns are formed with a pitch that is different from the second photoresist patterns.

3. The photo mask structure according to claim 1, wherein the first photoresist patterns have the same pitch as the second photoresist patterns.

4. The photo mask structure according to claim 1, further comprising:
a first photo mask, wherein the first mask patterns are disposed apart from each other on the first photo mask; and
a second photo mask, wherein the second mask patterns are disposed apart from each other on the second photo mask.

5. A method of using a photo mask structure on photoresist layers, the method comprising:
performing a first photo process on a first photoresist layer of the photoresist layers using first mask patterns of the photo mask structure to form first photoresist patterns on first regions of a semiconductor substrate; and
performing a second photo process on a second photoresist layer of the photoresist layers using second mask patterns of the photo mask structure to form second photoresist patterns on second regions of the semiconductor substrate,
wherein the second photoresist patterns are interposed between the first photoresist patterns and overlap the first photoresist patterns.

6. The method according to claim 5, wherein performing the first photo process comprises:
forming the first photoresist layer on the semiconductor substrate;
exposing the first mask patterns of the photo mask structure on the first photoresist layer; and
developing the first photoresist layer.

7. The method according to claim 6, wherein the first photoresist layer is formed using a positive-tone resist.

8. The method according to claim 6, wherein the first photoresist layer is formed using a negative-tone resist.

9. The method according to claim 6, further comprising:
forming an anti-reflective layer on the semiconductor substrate before forming the first photoresist layer.

10. The method according to claim 5, wherein performing the second photo process comprises:
forming the second photoresist layer on the semiconductor substrate having the second photoresist patterns;
exposing the second mask patterns of the photo mask on the second photoresist layer; and
developing the second photoresist layer.

11. The method according to claim 10, wherein the second photoresist layer is formed using a negative-tone resist.

12. The method according to claim 10, wherein the second photoresist layer is formed using a positive-tone resist.

13. The method according to claim 10, further comprising:
performing contact enhancement treatment on the semiconductor substrate having the first photoresist patterns before forming the second photoresist layer.

14. The method according to claim 13, wherein the contact enhancement treatment is performed using an HDMS.

15. The method according to claim 10, further comprising:
rinsing the second photoresist layer using a surfactant after developing the second photoresist layer.

16. The method according to claim 5, wherein the first photoresist patterns are different in pitch from the second photoresist patterns.

17. The method according to claim 5, wherein the first photoresist patterns have the same pitch as the second photoresist patterns.

18. The method according to claim 5, wherein the performing the first photo process and the performing the second photo process each comprise using a photo light source selected from a group including DUV, KrF, and ArF.

19. The method according to claim 5, wherein the first mask patterns are disposed on a first photo mask and the second mask patterns are disposed on a second photo mask.
